(19) United States
(12) Patent Application Publication
(10) Pub. No.: US 2008/0210463 A1
(43) Pub. Date: Sep. 4, 2008

(54) Plastics Articles for Metalization with Improved Shaping Properties

(75) Inventors: Heiko Maas, Mannheim (DE); Rene Lochtman, Mannheim (DE); Wolfgang Gutting, Grossfischlingen (DE); Gerald Lippert, Lampertheim (DE); Michael Dahlke, Ludwigshafen (DE); Norbert Schneider, Altrip (DE); Volker Warzelhan, Weisenheim (DE); Jurgen Pfister, Speyer (DE); Norbert Wagner, Mutterstadt (DE); Norbert Niessner, Friedelsheim (DE); Bettina Sobotka, Mannheim (DE); Matthias Scheibitz, Kelkheim (DE)

Correspondence Address: CONNOLLY BOVE LODGE & HUTZ, LLP, P O BOX 2207, WILMINGTON, DE, 19899, US

(73) Assignee: BASF AKTIENGESELLSCHAFT, Ludwigshafen (DE)

(21) Appl. No.: 11/912,712

(22) PCT Filed: Apr. 26, 2006
(86) PCT No.: PCT/EP06/61844

§ 371 Date: Oct. 26, 2007

(30) Foreign Application Priority Data
Apr. 27, 2005 (DE) 102005019923.2
Oct. 6, 2005 (DE) 102005048122.1
Oct. 6, 2005 (DE) 102005048178.7
Dec. 9, 2005 (DE) 102005059324.0

(51) Int. Cl. H05K 9/00; B32B 5/16; C08K 3/08; C08K 3/10; B29C 47/06; B32B 37/14; B29C 39/00; B29C 45/00; C25D 5/48; C23C 16/44; B05D 3/10; C23C 14/34

(52) U.S. Cl. 174/388; 428/323; 428/328; 524/401; 264/173.16; 156/60; 264/299; 264/328.1; 205/220; 427/250; 427/337; 204/192.1

(57) ABSTRACT

Metalizable foils or sheets produced from a plastics mixture comprising, components A, B, C, and D, which gives a total of 100% by weight,
a from 5 to 50% by weight of a thermoplastic polymer as component A,
b from 50 to 95% by weight of a metal powder with an average particle diameter of from 0.01 to 100 μm where the normal electrode potential of the metal in acidic solution is more negative than that of silver, as component B,
c from 0 to 10% by weight of a dispersing agent as component C, and
d from 0 to 40% by weight of fibrous or particulate fillers or their mixtures as component D,
   wherein the tensile strain at break of component A is greater by a factor of from 11 to 100 than the tensile strain at break of the plastics mixture comprising components A, B, and, if present, C and D, and wherein the tensile strength of component A is greater by a factor of from 0.5 to 4 than the tensile strength of the plastics mixture comprising components A, B, and, if present, C and D.

The invention relates to metalizable foils or sheets produced from a plastics mixture comprising, based on the total weight of components A, B, C, and D, which gives a total of 100% by weight,
a from 5 to 50% by weight of a thermoplastic polymer as component A,
b from 50 to 95% by weight of a metal powder with an average particle diameter of from 0.01 to 100 μm (determined by the method defined in the description), where the normal electrode potential of the metal in acidic solution is more negative than that of silver, as component B,
c from 0 to 10% by weight of a dispersing agent as component C, and
d from 0 to 40% by weight of fibrous or particulate fillers or their mixtures as component D,
   wherein the tensile strain at break of component A (determined by the method defined in the description) is greater by a factor of from 1.1 to 100 than the tensile strain at break of the plastics mixture comprising components A, B, and, if present, C and D (determined by the method defined in the description), and wherein the tensile strength of component A (determined by the method defined in the description) is greater by a factor of from 0.5 to 4 than the tensile strength of the plastics mixture comprising components A, B, and, if present, C and D (determined by the method defined in the definition).

The invention further relates to thermoplastic molding compositions for production of these metalizable foils or sheets, to a pelletized material comprising these thermoplastic molding compositions, to composite layered foils or composite layered sheets, and to moldings, comprising these metalizable foils or sheets, to metalized polymer products comprising these foils or sheets, or composite layered foils or composite layered sheets, and moldings, to processes for production of these articles, to the use of these articles, and also to EMI shielding systems, such as absorbers, attenuators, or reflectors for electromagnetic radiation, oxygen scavengers, electrically conducting components, gas barriers, and decorative parts comprising these articles.

Plastics compositions comprising metal powders are known and are used in a wide variety of application sectors, and the same applies to metalized plastics foils or metalized plastics moldings.

By way of example, JP-A 2003-193103 describes polymer foils filled with metal powder as absorbers for electromagnetic radiation. WO 03/10226 discloses single- and multilayer, metal-filled polymer foils as oxygen scavengers. U.S. Pat. No. 5,147,718 describes multilayer plastics foils filled with metal powder as suitable radar absorbers.

Furthermore, plastics articles comprising metal powder can be metalized by a currentless and/or electroplating method. Metalized plastics articles of this type can be used as electrical components, for example, because they are electrically conductive. They are moreover widely used inter alia in the decorative sector, because they have lower weight and lower production costs than articles manufactured entirely from metal, while their appearance is identical.

WO 86/02882, DE-A 1 521 152, and DE-A 1 615 786 disclose the application of iron-comprising binder systems and iron-comprising lacquer systems to plastics products, and subsequently copper is deposited here by a currentless method, and this is followed by metalizing by an electroplating method. U.S. Pat. No. 6,410,847 teaches deposition of copper layers or nickel layers by a currentless method on metal-filled, injection-molded polymer moldings.

With regard to the application sectors mentioned and for formation of coherent and firmly adhering metal layers, it is generally desirable to maximize metal powder content in the plastic. However, as filler level rises there is generally an associated impairment of the mechanical properties of the plastics mixture, and therefore at high filler levels there is inadequate toughness, flexural strength, and formability, for example. The use of shaping processes for production involving complex molding of components from highly filled semifinished plastics products, such as foils, is therefore often subject to restriction or indeed impossible.

There are also known processes for metalizing of plastics in which metal powders are not necessarily present in the plastic. Although these processes substantially avoid the disadvantageous impairment of the mechanical properties of the plastic via high filler levels, a disadvantage in production of these metalized articles is the complicated pretreatment required of the plastic surface via chemical or physical processes of roughening or etching, and/or application of layers which act as primer or adhesion promoter and comprise noble metal, for example, these layers being essential for the deposition of coherent and firmly adhering metal layers.

The company publication “Räumliche spritzgegossene Schaltungsträger” [Three-dimensionally injection-molded circuit mounts] from Bayer AG (dated Jul. 31, 2000, described as KU 21131-0007 d, e/5672445) discloses by way of example processes in which a primer comprising organometallic compounds as catalyst is applied by printing to certain polymer substrates. Metalization by a currentless and, if appropriate, electroplating method then takes place. The metalized substrates can then be subjected to a forming process and finally plastic can be applied to the back of the material by an injection-molding process.

It is an object of the present invention to provide metalizable plastics parts which, when compared with known metalizable plastics parts, have improved mechanical properties, in particular improved toughness, flexural strength, and formability, and also improved processing properties, for example in forming processes for production involving complex molding of components, and which are metalizable without specific pretreatment of the plastics surface, while having comparably good usage properties with respect to, by way of example, metalizability by a currentless or electroplating method, absorption, attenuation, and reflection of electromagnetic radiation, or oxygen absorption.

Accordingly, the foils or sheets mentioned at the outset have been produced from a plastics mixture comprising, based on the total weight of components A, B, C, and D, which gives a total of 100% by weight,
a from 5 to 50% by weight of a thermoplastic polymer as component A,
b from 50 to 95% by weight of a metal powder with an average particle diameter of from 0.01 to 100 μm (determined by the method defined in the description), where the normal electrode potential of the metal in acidic solution is more negative than that of silver, as component B,
c from 0 to 10% by weight of a dispersing agent as component C, and
d from 0 to 40% by weight of fibrous or particulate fillers or their mixtures as component D,
   wherein it is important for the invention that the tensile strain at break of component A (determined by the method defined in the description) is greater by a factor of from 1.1 to 100 than the tensile strain at break of the plastics mixture comprising components A, B, and, if present, C and D (determined by the method defined in the description), and that the tensile strength of component A (determined by the method defined in the description) is greater by a factor of from 0.5 to 4 than the tensile strength of the plastics mixture comprising components A, B, and, if present, C and D (determined by the method defined in the description).

The invention also provides thermoplastic molding compositions for production of these foils or sheets, and provides a pelletized material comprising these thermoplastic molding compositions, and provides composite layered foils or composite layered sheets, and provides moldings comprising these foils or sheets, and provides metalized polymer products comprising these foils or sheets, or composite layered foils or composite layered sheets, and moldings, and provides processes for production of these articles, and provides the use of these articles, and also provides EMI shielding systems, such as absorbers, attenuators, or reflectors for electromagnetic radiation, oxygen scavengers, electrically conducting components, gas barriers, and decorative parts comprising these articles.

When comparison is made with known metalizable plastics parts, the inventive foils or sheets have improved mechanical properties, in particular improved toughness, flexural strength, and formability, and also improved processing properties, for example in forming processes for production involving complex molding of components, and are metalizable without specific pretreatment of the plastics surface, while having comparably good usage properties with respect to, by way of example, metalizability by a currentless or electroplating method, absorption, attenuation, and reflection of electromagnetic radiation, or oxygen absorption.

The inventive foils or sheets are described below, as also are the further inventive articles, processes, and uses.

Foils or Sheets:

In one embodiment of the invention, the inventive foils or sheets are based on a plastics mixture comprising, based on the total weight of components A, B, C, and D, which gives a total of 100% by weight,
a from 5 to 50% by weight, preferably from 10 to 40% by weight, particularly preferably from 20 to 30% by weight, of component A,
b from 50 to 95% by weight, preferably from 60 to 90% by weight, particularly preferably from 70 to 80% by weight, of component B,
c from 0 to 10% by weight, preferably from 0 to 8% by weight, particularly preferably from 0 to 5% by weight, of component C, and
d from 0 to 40% by weight, preferably from 0 to 30% by weight, particularly preferably from 0 to 10% by weight, of component D.

In one preferred embodiment of the invention, the inventive foils or sheets are based on a plastics mixture comprising a dispersing agent and comprising, based on the total weight of components A, B, C, and D, which gives a total of 100% by weight,
a from 5 to 49.9% by weight, preferably from 10 to 39.5% by weight, particularly preferably from 20 to 29% by weight, of component A,
b from 50 to 94.9% by weight, preferably from 60 to 89.5% by weight, particularly preferably from 70 to 79% by weight, of component B,
c from 0.1 to 10% by weight, preferably from 0.5 to 8% by weight, particularly preferably from 1 to 5% by weight, of component C, and
d from 0 to 40% by weight, preferably from 0 to 29.5% by weight, particularly preferably from 0 to 9% by weight, of component D.

A significant feature of the invention is that, besides the metal powder content (component B) defined by the % by weight mentioned in the plastics mixture, the tensile strain at break of component A is greater by a factor of from 1.1 to 100, preferably by a factor of from 1.2 to 50, particularly preferably by a factor of from 1.3 to 10, than the tensile strain at break of the plastics mixture comprising components A, B, and, if present, C and D, and at the same time the tensile strength of component A is greater by a factor of from 0.5 to 4, preferably by a factor of from 1 to 3, particularly preferably by a factor of from 1 to 2.5, than the tensile strength of the plastics mixture comprising components A, B, and, if present, C and D (a factor smaller than 1 meaning that the tensile strength of component A is smaller than the tensile strength of the plastics mixture comprising components A, B, and, if present, C and D);

these tensile strength values and tensile strain at break values and all others mentioned in this application are determined in the tensile test to ISO 527-2:1996 on test specimens of 1 BA type (Annex A of the standard mentioned: “small test specimens”).

The total thickness of the inventive foils or sheets is generally from 10 μm to 5 mm, preferably from 10 μm to 3 mm, particularly preferably from 20 μm to 1.5 mm, in particular from 100 μm to 300 μm.

The inventive foils or sheets are produced from a plastics mixture comprising the following components.

### Component A

In principle, any of the thermoplastic polymers is suitable as component A, in particular those whose tensile strain at break is in the range from 10% to 1000%, preferably in the range from 20 to 700, particularly preferably in the range from 50 to 500.

Examples of a suitable component A are polyethylene, polypropylene, polyvinyl chloride, polystyrene (impact-resistant or non-impact-modified), ABS (acrylonitrile-butadiene-styrene), ASA (acrylonitrile-styrene-acrylate), MABS (transparent ABS, comprising methacrylate units), styrene-butadiene block copolymer (e.g. Styroflex® or Styrolux® from BASF Aktiengesellschaft, K-Resin™ from CPC), polyamides, polyethylene terephthalate (PET), polyethylene terephthalate glycol (PETG), polybutylene terephthalate (PBT), aliphatic-aromatic copolyesters (e.g. Ecoflex® from BASF Aktiengesellschaft), polycarbonate (e.g. Makrolon® from Bayer AG), polymethyl methacrylate (PMMA), poly(ether) sulfones, and polyphenylene oxide (PPO).

As component A, preference is given to the use of one or more polymers selected from the group of impact-modified vinylaromatic copolymers, of thermoplastic elastomers based on styrene, of polyolefins, of aliphatic-aromatic copolyesters, of polycarbonates, and of thermoplastic polyurethanes.

Polyamides can be used as likewise preferred component A.

### Impact-Modified Vinylaromatic Copolymers:

Preferred impact-modified vinylaromatic copolymers are impact-modified copolymers composed of vinylaromatic monomers and of vinyl cyanides (SAN). The preferred impact-modified SAN used preferably comprises ASA polymers and/or ABS polymers, or else (meth)acrylate-acrylonitrile-butadiene-styrene polymers (“MABS”, transparent ABS), or else blends of SAN, ABS, ASA, and MABS with other thermoplastics, for example with polycarbonate, with polyamide, with polyethylene terephthalate, with polybutylene terephthalate, with PVC, or with polyolefins.

The tensile strain at break values of the ASA and ABS that can be used as components A are generally from 10% to 300%, preferably from 15 to 250%, particularly preferably from 20% to 200%.

ASA polymers are generally impact-modified SAN polymers which comprise elastomeric graft copolymers of vinylaromatic compounds, in particular styrene, and vinyl cyanides, in particular acrylonitrile, on polyalkyl acrylate rubbers in a copolymer matrix composed, in particular, of styrene and/or α-methylstyrene and acrylonitrile.

In one preferred embodiment in which the foils or sheets comprise ASA polymers, the elastomeric graft copolymer A^{R} of component A is composed of
a1 from 1 to 99% by weight, preferably from 55 to 80% by weight, in particular from 55 to 65% by weight, of a particulate graft base A1 with a glass transition temperature below 0° C.,
a2 from 1 to 99% by weight, preferably from 20 to 45% by weight, in particular from 35 to 45% by weight, of a graft A2 composed of the following monomers, based on A2,
a21 from 40 to 100% by weight, preferably from 65 to 85% by weight, of units of styrene, of a substituted styrene, or of a (meth)acrylate, or of a mixture of these, in particular of styrene and/or α-methylstyrene, as component A21, and
a22 up to 60% by weight, preferably from 15 to 35% by weight, of units of acrylonitrile or methacrylonitrile, in particular of acrylonitrile, as component A22.

The graft A2 here is composed of at least one graft shell.

Component A1 here is composed of the following monomers
a11 from 80 to 99.99% by weight, preferably from 95 to 99.9% by weight, of at least one C₁-C₈-alkyl acrylate, preferably n-butyl acrylate and/or ethylhexyl acrylate, as component A11,
a12 from 0.01 to 20% by weight, preferably from 0.1 to 5.0% by weight, of at least one polyfunctional crosslinking monomer, preferably diallyl phthalate and/or DCPA, as component A12.

According to one embodiment of the invention, the average particle size of component A^{R} is from 50 to 1000 nm, with monomodal distribution.

In another embodiment of the invention, the particle size distribution of component A^{R} is bimodal, from 60 to 90% by weight having an average particle size of from 50 to 200 nm, and from 10 to 40% by weight having an average particle size of from 50 to 400 nm, based on the total weight of component A^{R}.

The average particle size and particle size distribution given are the sizes determined from the cumulative weight distribution. The average particle sizes according to the invention are in all cases the weight average of the particle sizes. The determination of these is based on the method of W. Scholtan and H. Lange, Kolloid-Z. und Z.-Polymere 250 (1972), pp. 782-796, using an analytical ultracentrifuge. The ultracentrifuge measurement gives the cumulative weight distribution of the particle diameter of a specimen. From this it is possible to deduce what percentage by weight of the particles have a diameter identical to or smaller than a particular size. The average particle diameter, which is also termed the d₅₀ of the cumulative weight distribution, is defined here as that particle diameter at which 50% by weight of the particles have a diameter smaller than that corresponding to the d₅₀. Equally, 50% by weight of the particles then have a larger diameter than the d₅₀. To describe the breadth of the particle size distribution of the rubber particles, d₁₀ and d₉₀ values given by the cumulative weight distribution are utilized alongside the d₅₀ value (average particle diameter). The d₁₀ and d₉₀ of the cumulative weight distribution are defined similarly to the d₅₀ with the difference that they are based on, respectively, 10 and 90% by weight of the particles. The quotient

d₉₀−d₁₀)/d₅₀=Q

is a measure of the breadth of the particle size distribution. Elastomeric graft copolymers A^{R} preferably have Q less than 0.5, in particular less than 0.35.

The acrylate rubbers A1 are preferably alkyl acrylate rubbers composed of one or more C₁-C₈-alkyl acrylates, preferably C₄-C₈-alkyl acrylates, preferably with use of at least some butyl, hexyl, octyl or 2-ethylhexyl acrylate, in particular n-butyl and 2-ethylhexyl acrylate. These alkyl acrylate rubbers may comprise, as comonomers, up to 30% by weight of hard-polymer-forming monomers, such as vinyl acetate, (meth)acrylonitrile, styrene, substituted styrene, methyl methacrylate, vinyl ether.

The acrylate rubbers also comprise from 0.01 to 20% by weight, preferably from 0.1 to 5% by weight, of crosslinking, polyfunctional monomers (crosslinking monomers).

Examples of these are monomers which comprise two or more double bonds capable of copolymerization, preferably not 1,3-conjugated.

Examples of suitable crosslinking monomers are divinylbenzene, diallyl maleate, diallyl fumarate, diallyl phthalate, diethyl phthalate, triallyl cyanurate, triallyl isocyanurate, tricyclodecenyl acrylate, dihydrodicyclopentadienyl acrylate, triallyl phosphate, allyl acrylate, allyl methacrylate. Dicyclopentadienyl acrylate (DCPA) has proven to be a particularly suitable crosslinking monomer (cf. DE-C 12 60 135).

Component A^{R} is a graft copolymer. These graft copolymers A^{R} have an average particle size d₅₀ of from 50 to 1000 nm, preferably from 50 to 800 nm, and particularly preferably from 50 to 600 nm. These particle sizes may be achieved if the graft base A1 used has a particle size of from 50 to 800 nm, preferably from 50 to 500 nm, and particularly preferably from 50 to 250 nm. The graft copolymer A^{R} generally has one or more stages, i.e. is a polymer composed of a core and one or more shells. The polymer is composed of a first stage (graft core) A1 and of one or—preferably—more stages A2 (grafts) grafted onto this first stage and known as graft stages or graft shells.

Simple grafting or multiple stepwise grafting may be used to apply one or more graft shells to the rubber particles, and each of these graft shells may have a different makeup. In addition to the grafting monomers, polyfunctional crosslinking monomers or monomers comprising reactive groups may also be included in the grafting process (see, for example, EP-A 230 282, DE-B 36 01 419, EP-A 269 861).

In one preferred embodiment, component A^{R} is composed of a graft copolymer built up in two or more stages, the graft stages generally being prepared from resin-forming monomers and having a glass transition temperature T_{g} above 30° C., preferably above 50° C. The structure having two or more stages serves, inter alia, to make the rubber particles A^{R} (partially) compatible with the thermoplastic matrix.

An example of a preparation method for graft copolymers A^{R} is grafting of at least one of the monomers A2 listed below onto at least one of the graft bases or graft core materials A1 listed above.

In one embodiment of the invention, the graft base A1 is composed of from 15 to 99% by weight of acrylate rubber, from 0.1 to 5% by weight of crosslinker, and from 0 to 49.9% by weight of one of the stated other monomers or rubbers.

Suitable monomers for forming the graft A2 are styrene, α-methylstyrene, (meth)acrylates, acrylonitrile, and methacrylonitrile, in particular acrylonitrile.

In one embodiment of the invention, crosslinked acrylate polymers with a glass transition temperature below 0° C. serve as graft base A1. The crosslinked acrylate polymers are preferably to have a glass transition temperature below −20° C., in particular below −30° C.

In one preferred embodiment, the graft A2 is composed of at least one graft shell, and the outermost graft shell of these has a glass transition temperature of more than 30° C. while a polymer formed from the monomers of the graft A2 would have a glass transition temperature of more than 80° C.

Suitable preparation processes for graft copolymers A^{R} are emulsion, solution, bulk, or suspension polymerization. The graft copolymers A^{R} are preferably prepared by free-radical emulsion polymerization in the presence of lattices of component A1 at from 20° C. to 90° C., using water-soluble or oil-soluble initiators, such as peroxodisulfate or benzoyl peroxide, or with the aid of redox initiators. Redox initiators are also suitable for polymerization below 20° C.

Suitable emulsion polymerization processes are described in DE-A 28 26 925, 31 49 358, and DE-C 12 60 135.

The graft shells are preferably built up in the emulsion polymerization process described in DE-A 32 27 555, 31 49 357, 31 49 358, 34 14 118. The defined setting of the particle sizes of the invention of from 50 to 1000 nm preferably takes place by the processes described in DE-C 12 60 135 and DE-A 28 26 925, and Applied Polymer Science, volume 9 (1965), p. 2929. The use of polymers with different particle sizes is known from DE-A 28 26 925 and US-A 5 196 480, for example.

The process described in DE-C 12 60 135 begins by preparing the graft base A1 by polymerizing in a known manner, at from 20 to 100° C., preferably from 50 to 80° C., the acrylate(s) used in one embodiment of the invention and the polyfunctional crosslinking monomer, if appropriate together with the other comonomers, in aqueous emulsion. Use may be made of the usual emulsifiers, such as alkali metal alkyl- or alkylaryl-sulfonates, alkyl sulfates, fatty alcohol sulfonates, salts of higher fatty acids having from 10 to 30 carbon atoms or resin soaps. It is preferable to use the sodium salts of alkylsulfonates or fatty acids having from 10 to 18 carbon atoms. In one embodiment, the amounts used of the emulsifiers are from 0.5 to 5% by weight, in particular from 1 to 2% by weight, based on the monomers used in preparing the graft base A1. Operations are generally carried out with a ratio of water to monomers of from 2:1 to 0.7:1 by weight. The polymerization initiators used are in particular the commonly used persulfates, such as potassium persulfate. However, it is also possible to use redox systems. The amounts generally used of the initiators are from 0.1 to 1% by weight, based on the monomers used in preparing the graft base A1. Other polymerization auxiliaries which may be used during the polymerization are the usual buffer substances which can set a preferred pH of from 6 to 9, examples being sodium bicarbonate and sodium pyrophosphate, and also from 0 to 3% by weight of a molecular weight regulator, such as mercaptans, terpinols or dimeric α-methylstyrene. The precise polymerization conditions, in particular the nature, feed parameters, and amount of the emulsifier, are determined individually within the ranges given above in such a way that the resultant latex of the crosslinked acrylate polymer has a d₅₀ in the range from about 50 to 800 nm, preferably from 50 to 500 nm, particularly preferably in the range from 80 to 250 nm. The particle size distribution of the latex here is preferably intended to be narrow.

In one embodiment of the invention, to prepare the graft polymer A^{R}, in a following step, in the presence of the resultant latex of the crosslinked acrylate polymer, a monomer mixture composed of styrene and acrylonitrile is polymerized, and in one embodiment of the invention here the weight ratio of styrene to acrylonitrile in the monomer mixture should be in the range from 100:0 to 40:60, and preferably from 65:35 to 85:15. This graft copolymerization of styrene and acrylonitrile onto the crosslinked polyacrylate polymer serving as a graft base is again advantageously carried out in aqueous emulsion under the usual conditions described above. The graft copolymerization may usefully take place in the system used for the emulsion polymerization to prepare the graft base A1, where further emulsifier and initiator may be added if necessary. The mixture of styrene and acrylonitrile monomers which is to be grafted on in one embodiment of the invention may be added to the reaction mixture all at once, in portions in more than one step, or preferably continuously during the course of the polymerization. The graft copolymerization of the mixture of styrene and acrylonitrile in the presence of the crosslinking acrylate polymer is carried out in such a way as to obtain in graft copolymer A^{R} a degree of grafting of from 1 to 99% by weight, preferably from 20 to 45% by weight, in particular from 35 to 45% by weight, based on the total weight of component A^{R}. Since the grafting yield in the graft copolymerization is not 100%, the amount of the mixture of styrene and acrylonitrile monomers which has to be used in the graft copolymerization is somewhat greater than that which corresponds to the desired degree of grafting. Control of the grafting yield in the graft copolymerization, and therefore of the degree of grafting of the finished graft copolymer A^{R} is a topic with which the person skilled in the art is familiar. It may be achieved, for example, via the metering rate of the monomers or via addition of regulators (Chauvel, Daniel, ACS Polymer Preprints 15 (1974), pp. 329 ff.). The emulsion graft copolymerization generally gives approximately 5 to 15% by weight, based on the graft copolymer, of free, ungrafted styrene-acrylonitrile copolymer. The proportion of the graft copolymer A^{R} in the polymerization product obtained in the graft copolymerization is determined by the method given above. Preparation of the graft copolymers A^{R} by the emulsion process also gives, besides the technical process advantages stated above, the possibility of reproducible changes in particle sizes, for example by agglomerating the particles at least to some extent to give larger particles. This implies that polymers with different particle sizes may also be present in the graft copolymers A^{R}. Component A^{R} composed of graft base and graft shell(s) can in particular be ideally adapted to the respective application, in particular with regard to particle size.

The graft copolymers A^{R} generally comprise from 1 to 99% by weight, preferably from 55 to 80% by weight, and particularly preferably from 55 to 65% by weight, of-graft base A1 and from 1 to 99% by weight, preferably from 20 to 45% by weight, particularly preferably from 35 to 45% by weight, of the graft A2, based in each case on the entire graft copolymer.

ABS polymers are generally understood to be impact-modified SAN polymers in which diene polymers, in particular poly-1,3-butadiene, are present in a copolymer matrix, in particular of styrene and/or α-methylstyrene, and acrylonitrile.

In one preferred embodiment, in which the foils or sheets comprise ABS polymers, the elastomeric graft copolymer A^{R}′ of component A is composed of
a1′ from 10 to 90% by weight of at least one elastomeric graft base with a glass transition temperature below 0° C., obtainable by polymerizing, based on A1′,
a11′ from 60 to 100% by weight, preferably from 70 to 100% by weight, of at least one conjugated diene and/or C₁-C₁₀-alkyl acrylate, in particular butadiene, isoprene, n-butyl acrylate and/or 2-ethylhexyl acrylate,
a12′ from 0 to 30% by weight, preferably from 0 to 25% by weight, of at least one other monoethylenically unsaturated monomer, in particular styrene, (X-methyl-styrene, n-butyl acrylate, methyl methacrylate, or a mixture of these, and among the last-named in particular butadiene-styrene copolymers and n-butyl acrylate-styrene copolymers, and
a13′ from 0 to 10% by weight, preferably from 0 to 6% by weight, of at least one crosslinking monomer, preferably divinylbenzene, diallyl maleate, allyl (meth)acrylate, dihydrodicyclopentadienyl acrylate, divinyl esters of dicarboxylic acids, such as succinic and adipic acid, and diallyl and divinyl ethers of bifunctional alcohols, such as ethylene glycol or butane-1,4-diol,
a2′ from 10 to 60% by weight, preferably from 15 to 55% by weight, of a graft A2′, composed of, based on A2′,
a21′ from 50 to 100% by weight, preferably from 55 to 90% by weight, of at least one vinylaromatic monomer, preferably styrene and/or α-methylstyrene,
a22′ from 5 to 35% by weight, preferably from 10 to 30% by weight, of acrylonitrile and/or methacrylonitrile, preferably acrylonitrile,
a23′ from 0 to 50% by weight, preferably from 0 to 30% by weight, of at least one other monoethylenically unsaturated monomer, preferably methyl methacrylate and n-butyl acrylate.

In another preferred embodiment in which the foils or sheets comprise ABS, component A^{R}′ is a graft rubber with bimodal particle size distribution, composed of, based on A^{R}′,
a1″ from 40 to 90% by weight, preferably from 45 to 85% by weight, of an elastomeric particulate graft base A1″, obtainable by polymerizing, based on A1″,
a11″ from 70 to 100% by weight, preferably from 75 to 100% by weight, of at least one conjugated diene, in particular butadiene and/or isoprene,
a12″ from 0 to 30% by weight, preferably from 0 to 25% by weight, of at least one other monoethylenically unsaturated monomer, in particular styrene, α-methyl-styrene, n-butyl acrylate, or a mixture of these,
a2″ from 10 to 60% by weight, preferably from 15 to 55% by weight, of a graft A2″ composed of, based on A2″,
a21″ from 65 to 95% by weight, preferably from 70 to 90% by weight, of at least one vinylaromatic monomer, preferably styrene,
a22″ from 5 to 35% by weight, preferably from 10 to 30% by weight, of acrylonitrile,
a23″ from 0 to 30% by weight, preferably from 0 to 20% by weight, of at least one other monoethylenically unsaturated monomer, preferably methyl methacrylate and n-butyl acrylate.

In one preferred embodiment, in which the foils or sheets comprise ASA polymers as component A, the hard matrix A^{M} of component A is at least one hard copolymer which comprises units which derive from vinylaromatic monomers, and comprising, based on the total weight of units deriving from vinylaromatic monomers, from 0 to 100% by weight, preferably from 40 to 100% by weight, particularly preferably from 60 to 100% by weight, of units deriving from α-methylstyrene, and comprising from 0 to 100% by weight, preferably from 0 to 60% by weight, particularly preferably from 0 to 40% by weight of units deriving from styrene, composed of, based on A^{M}′,
a^{M}1′ from 40 to 100% by weight, preferably from 60 to 85% by weight, of vinylaromatic units, as component A^{M}1,
a^{M}2 up to 60% by weight, preferably from 15 to 40% by weight of units of acrylonitrile or of methacrylonitrile, in particular of acrylonitrile, as component A^{M}2.

In one preferred embodiment, in which the foils or sheets comprise ABS polymers as component A, the hard matrix A^{M}′ of component A is at least one hard copolymer which comprises units which derive from vinylaromatic monomers, and comprising, based on the total weight of units deriving from vinylaromatic monomers, from 0 to 100% by weight preferably from 40 to 100% by weight, particularly preferably from 60 to 100% by weight, of units deriving from α-methylstyrene, and from 0 to 100% by weight, preferably from 0 to 60% by weight, particularly preferably from 0 to 40% by weight, of units deriving from styrene, composed of, based on A^{M}′,
a^{M}1′ from 50 to 100% by weight, preferably from 55 to 90% by weight, of vinylaromatic monomers,
a^{M}2′ from 0 to 50% by weight of acrylonitrile or methacrylonitrile or a mixture of these,
a^{M}3′ from 0 to 50% by weight of at least one other monoethylenically unsaturated monomer, such as methyl methacrylate and N-alkyl- or N-arylmaleimides, e.g. N-phenylmaleimide.

In another preferred embodiment, in which the foils or sheets comprise ABS as component A, component A^{M}′ is at least one hard copolymer with a viscosity number VN (determined to DIN 53726 at 25° C. in 0.5% strength by weight solution in dimethyl-formamide) of from 50 to 120 ml/g, comprising units which derive from vinylaromatic monomers, and comprising, based on the total weight of units deriving from vinyl-aromatic monomers, from 0 to 100% by weight, preferably from 40 to 100% by weight, particularly preferably from 60 to 100% by weight, of units deriving from α-methyl-styrene, and from 0 to 100% by weight, preferably from 0 to 60% by weight, particularly preferably from 0 to 40% by weight, of units deriving from styrene, composed of, based on A^{M}′,
a_{M}1″ from 69 to 81% by weight, preferably from 70 to 78% by weight, of vinylaromatic monomers,
a_{M}2″ from 19 to 31% by weight, preferably from 22 to 30% by weight, of acrylonitrile,
a_{M}3″ from 0 to 30% by weight, preferably from 0 to 28% by weight, of at least one other monoethylenically unsaturated monomer, such as methyl methacrylate or N-alkyl- or N-arylmaleimides, e.g. N-phenylmaleimide.

In one embodiment the ABS polymers comprise, alongside one another, components A^{M}′ whose viscosity numbers VN differ by at least five units (ml/g) and/or whose acrylonitrile contents differ by five units (% by weight). Finally, alongside component A^{M}′ and the other embodiments, there may also be copolymers present of α-methylstyrene with maleic anhydride or maleimides, of α-methylstyrene with maleimides and methyl methacrylate or acrylonitrile, or of α-methylstyrene with maleimides, methyl methacrylate, and acrylonitrile.

In these ABS polymers, the graft polymers A^{R}′ are preferably obtained by means of emulsion polymerization. The mixing of the graft polymers A^{R}′ with components A^{M}′, and, if appropriate, other additives generally takes place in a mixing apparatus, producing a substantially molten polymer mixture. It is advantageous for the molten polymer mixture to be cooled very rapidly.

In other respects, the preparation process and general embodiments, and particular embodiments, of the abovementioned ABS polymers are described in detail in the German patent application DE-A 19728629, expressly incorporated herein by way of reference. The ABS polymers mentioned may comprise other conventional auxiliaries and fillers. Examples of these substances are lubricants or mold-release agents, waxes, pigments, dyes, flame retardants, antioxidants, light stabilizers, or antistatic agents.

According to one preferred embodiment of the invention, the viscosity number of the hard matrices A^{M} and, respectively, A^{M}′ of component A is from 50 to 90, preferably from 60 to 80.

The hard matrices A^{M} and, respectively, A^{M}′ of component A are preferably amorphous polymers. According to one embodiment of the invention, mixtures of a copolymer of styrene with acrylonitrile and of a copolymer composed of α-methylstyrene with acrylonitrile are used as hard matrices A^{M} and, respectively, A^{M}′ of component A. The acrylonitrile content in these copolymers of the hard matrices is from 0 to 60% by weight, preferably from 15 to 40% by weight, based on the total weight of the hard matrix. The hard matrices A^{M} and, respectively, A^{M}′ of component A also include the free, ungrafted α-methylstyrene-acrylonitrile copolymers produced during the graft copolymerization reaction to prepare component A^{R} and, respectively, A^{R}′. Depending on the conditions selected during the graft copolymerization reaction for preparing the graft copolymers A^{R} and, respectively, A^{R}′, it can be possible for a sufficient proportion of hard matrix to have been formed before the graft copolymerization reaction has ended. However, it will generally be necessary for the products obtained during the graft copolymerization reaction to be blended with additional, separately prepared hard matrix.

The additional, separately prepared hard matrices A^{M} and, respectively, A^{M}′ of component A may be obtained by the conventional processes. For example, according to one embodiment of the invention the copolymerization reaction of the styrene and/or α-methylstyrene with the acrylonitrile may be carried out in bulk, solution, suspension, or aqueous emulsion. The viscosity number of component A^{M} and, respectively, A^{M}′ is preferably from 40 to 100, with preference from 50 to 90, in particular from 60 to 80. The viscosity number here is determined to DIN 53 726, dissolving 0.5 g of material in 100 ml of dimethylformamide.

The mixing of components A^{R} (and, respectively, A^{R}′) and A^{M} (and, respectively, A^{M}′) may take place in any desired manner by any of the known methods. If, by way of example, these components have been prepared via emulsion polymerization, it is possible to mix the resultant polymer dispersions with one another, then to precipitate the polymers together and work up the polymer mixture. However, these components are preferably blended via rolling or kneading or extrusion of the components together, the components having been isolated, if necessary, in advance from the aqueous dispersion or solution obtained during the polymerization reaction. The graft copolymerization products obtained in aqueous dispersion may also be only partially dewatered and mixed in the form of moist crumb with the hard matrix, whereupon then the complete drying of the graft copolymers takes place during the mixing process.

### Thermoplastic Elastomers Based on Styrene:

Preferred styrene-based thermoplastic elastomers (S-TPE) are those whose tensile strain at break is more than 300%, particularly preferably more than 500%, in particular more than 500% to 600%. The S-TPE admixed particularly preferably comprises a linear or star-shaped styrene-butadiene block copolymer having external polystyrene blocks S and, situated between these, styrene-butadiene copolymer blocks having random styrene/butadiene distribution (S/B)_{random} or having a styrene gradient (S/B)ₜₐₚₑᵣ (e.g. Styroflex® or Styrolux® from BASF Aktiengesellschaft, K-Resin™ from CPC).

The total butadiene content is preferably in the range from 15 to 50% by weight, particularly preferably in the range from 25 to 40% by weight, and the total styrene content is correspondingly preferably in the range from 50 to 85% by weight, particularly preferably in the range from 60 to 75% by weight.

The styrene-butadiene block (S/B) is preferably composed of from 30 to 75% by weight of styrene and from 25 to 70% by weight of butadiene. An (S/B) block particularly preferably has a butadiene content of from 35 to 70% by weight and a styrene content of from 30 to 65% by weight.

The content of the polystyrene blocks S is preferably in the range from 5 to 40% by weight, in particular in the range from 25 to 35% by weight, based on the entire block copolymer. The content of the copolymer blocks S/B is preferably in the range from 60 to 95% by weight, in particular in the range from 65 to 75% by weight.

Particular preference is given to linear styrene-butadiene block copolymers of the general structure S-(S/B)-S having, situated between the two S blocks, one or more (S/B)_{random} blocks having random styrene/butadiene distribution. Block copolymers of this type are obtainable via anionic polymerization in a non-polar solvent with addition of a polar cosolvent or of a potassium salt, as described by way of example in WO 95/35335 or WO 97/40079.

The vinyl content is the relative content of 1,2-linkages of the diene units, based on the entirety of 1,2-, and 1,4-cis and 1,4-trans linkages. The 1,2-vinyl content in the styrene/butadiene copolymer block (S/B) is preferably below 20%, in particular in the range from 10 to 18%, particularly preferably in the range from 12 to 16%.

### Polyolefins:

The polyolefins that can be used as components A generally have tensile strain at break values of from 10% to 600%, preferably from 15% to 500%, particularly preferably from 20% to 400%.

Examples of suitable components A are semicrystalline polyolefins, such as homo- or copolymers of ethylene, propylene, 1-butene, 1-pentene, 1-hexene, or 4-methyl-1-pentene, or else ethylene copolymers with vinyl acetate, vinyl alcohol, ethyl acrylate, butyl acrylate, or methacrylate. The component A used preferably comprises a high-density polyethylene (HDPE), low-density polyethylene (LDPE), linear low-density polyethylene (LLDPE), polypropylene (PP), ethylene-vinyl acetate copolymer (EVA), or ethylene-acrylic copolymer. A particularly preferred component A is polypropylene.

### Polycarbonates:

The polycarbonates that can be used as components A generally have tensile strain at break values of from 20% to 300%, preferably 30% to 250%, particularly preferably 40% to 200%.

The molar mass of polycarbonates suitable as component A (weight average M1, determined by means of gel permeation chromatography in tetrahydrofuran against polystyrene standards) is preferably in the range from 10 000 to 60 000 g/mol. By way of example, they are obtainable by the processes of DE-B-1 300 266 via interfacial polycondensation or according to the process of DE-A-1 495 730 via reaction of diphenyl carbonate with bisphenols. Preferred bisphenol is 2,2-di(4-hydroxy-phenyl)propane, generally—and also hereinafter—termed bisphenol A.

Instead of bisphenol A, it is also possible to use other aromatic dihydroxy compounds, in particular 2,2-di(4-hydroxyphenyl)pentane, 2,6-dihydroxynaphthalene, 4,4′-di-hydroxydiphenyl sulfane, 4,4′-dihydroxydiphenyl ether, 4,4′-dihydroxydiphenyl sulfite, 4,4′-dihydroxydiphenylmethane, 1,1-di(4-hydroxyphenyl)ethane, 4,4-dihydroxydiphenyl, or dihydroxydiphenylcycloalkanes, preferably dihydroxydiphenylcyclohexanes, or dihydroxycyclopentanes, in particular 1,1-bis(4-hydroxyphenyl)-3,3,5-trimethylcyclo-hexane, or else a mixture of the abovementioned dihydroxy compounds.

Particularly preferred polycarbonates are those based on bisphenol A or bisphenol A together with up to 80 mol % of the abovementioned aromatic dihydroxy compounds.

Polycarbonates with particularly good suitability as component A are those which comprise units that derive from resorcinol esters or from alkylresorcinol esters, for example those described in WO 00/61664, WO 00/15718, or WO 00/26274. These polycarbonates are marketed by way of example by General Electric Company, the trademark being SollX®.

It is also possible to use copolycarbonates according to US-A 3 737 409, and copolycarbonates based on bisphenol A and di(3,5-dimethyldihydroxyphenyl) sulfone are of particular interest here, and feature high heat resistance. It is also possible to use mixtures of different polycarbonates.

According to the invention, the average molar masses (weight average Mw, determined by means of gel permeation chromatography in tetrahydrofuran against polystyrene standards) of the polycarbonates are in the range from 10 000 to 64 000 g/mol. They are preferably in the range from 15 000 to 63 000 g/mol, in particular in the range from 15 000 to 60 000 g/mol. This means that the relative solution viscosities of the polycarbonates are in the range from 1.1 to 1.3, measured in 0.5% strength by weight solution in dichloromethane at 25° C., preferably from 1.15 to 1.33. The difference between the relative solution viscosities of the polycarbonates used is preferably not more than 0.05, in particular not more than 0.04.

The form in which the polycarbonates are used may either be that of regrind or else that of pellets.

### Thermoplastic Polyurethane:

Any aromatic or aliphatic thermoplastic polyurethane is generally suitable as component A, and amorphous aliphatic thermoplastic polyurethanes which are transparent have preferred suitability. Aliphatic thermoplastic polyurethanes and their preparation are known to the person skilled in the art, for example from EP-B1 567 883 or DE-A 10321081, and are commercially available, for example with trademarks Texin® and Desmopan® from Bayer Aktiengesellschaft.

The Shore hardness D of preferred aliphatic thermoplastic polyurethanes is from 45 to 70, and their tensile strain at break values are from 30% to 800%, preferably from 50% to 600%, particularly preferably from 80% to 500%.

Particularly preferred components A are the thermoplastic elastomers based on styrene.

### Component B

Any of the metal powders whose average particle diameter (determined via laser diffraction measurement in Microtrac X100 equipment) is from 0.01 to 100 μm, preferably from 0.1 to 50 μm, particularly preferably from 1 to 10 μm, is suitable as component B, as long as the normal electrode potential in acidic solution of the metal is more negative than that of silver.

Zn, Ni, Cu, Sn, Co, Mn, Fe, M_{g}, Pb, Cr, and Bi are examples of suitable metals. The form in which the metals are deposited here may be that of the metal used or—if various metals are used—that of alloys of the metals mentioned with one another or with other metals. Examples of suitable alloys are CuZn, CuSn, CuNi, SnPb, SnBi, SnCu, NiP, ZnFe, ZnNi, ZnCo, and ZnMn. Iron powder and copper powder, in particular iron powder, are preferred metal powders that may be used.

The metal powder particles may in principle have any desired shape and by way of example are acicular, lamellar, or spherical, preference being given to spherical and lamellar metal particles. Metal particles of this type are readily available commercial products, or can easily be prepared by means of known processes, for example via electrolytic deposition or chemical reduction from solutions of the metal salts, or via reduction of an oxidic powder, for example by means of hydrogen, or via spraying of a molten metal, in particular into cooling fluids, such as gases or water.

It is particularly preferable to use metal powders with spherical particles, in particular carbonyl iron powders.

The preparation of carbonyl iron powders via thermal decomposition of pentacarbonyl iron is known and is described by way of example in Ullmann's Encyclopedia of Industrial Chemistry, 5th Edition, Volume A14, page 599. By way of example, the pentacarbonyl iron may be decomposed at elevated temperatures and elevated pressures in a heatable decomposition system which comprises a tube composed of a heat-resistant material, such as quartz glass or V2A steel in preferably vertical position, surrounded by heating equipment, for example composed of heating tapes, of heating wires, or of a heating jacket through which a hot fluid passes.

The average particle diameters of the carbonyl iron powders undergoing deposition can be controlled within a wide range via the process parameters and reaction conduct during the decomposition process and are generally from 0.01 to 100 μm, preferably from 0.1 to 50 μm, particularly preferably from 1 to 10 μm.

### Component C

In principle, any of the dispersing agents described in the prior art and known to the person skilled in the art for use in plastics mixtures is suitable as component C. Preferred dispersing agents are surfactants or surfactant mixtures, such as anionic, cationic, amphoteric or nonionic surfactants.

Cationic and anionic surfactants are described by way of example in “Encyclopedia of Polymer Science and Technology”, J. Wiley & Sons (1966), Volume 5, pp. 816 to 818, and in “Emulsion Polymerisation and Emulsion Polymers”, editors P. Lovell and M. El-Asser, Verlag Wiley & Sons (1997), pp. 224-226.

Examples of anionic surfactants are alkali metal salts of organic carboxylic acids having chain lengths of from 8 to 30 carbon atoms, preferably from 12 to 18 carbon atoms. These are generally termed soaps. The salts usually used are the sodium, potassium, or ammonium salts. Other anionic surfactants which may be used are alkyl sulfates and alkyl- or alkylarylsulfonates having from 8 to 30 carbon atoms, preferably from 12 to 18 carbon atoms. Particularly suitable compounds are alkali metal dodecyl sulfates, e.g. sodium dodecyl sulfate or potassium dodecyl sulfate, and alkali metal salts of C₁₂-C₁₆ paraffinsulfonic acids. Other suitable compounds are sodium dodecylbenzenesulfonate and sodium dioctyl sulfosuccinate.

Examples of suitable cationic surfactants are salts of amines or of diamines, quaternary ammonium salts, e.g. hexadecyltrimethylammonium bromide, and also salts of long-chain substituted cyclic amines, such as pyridine, morpholine, piperidine. Use is particularly made of quaternary ammonium salts of trialkylamines, e.g. hexadecyltri-methylammonium bromide. The alkyl radicals here preferably have from 1 to 20 carbon atoms.

According to the invention, nonionic surfactants may in particular be used as component C. Nonionic surfactants are described by way of example in CD Römpp Chemie Lexikon—Version 1.0, Stuttgart/N.Y. Georg Thieme Verlag 1995, keyword “Nichtionische Tenside” [Nonionic surfactants].

Examples of suitable nonionic surfactants are polyethylene-oxide- or polypropylene-oxide-based substances, such as Pluronic® or Tetronic® from BASF Aktiengesellschaft. Polyalkylene glycols suitable as nonionic surfactants generally have a molar mass Mₙ in the range from 1 000 to 15 000 g/mol, preferably from 2 000 to 13 000 g/mol, particularly preferably from 4 000 to 11 000 g/mol. Preferred nonionic surfactants are polyethylene glycols.

The polyalkylene glycols are known per se or may be prepared by processes-known per se, for example by anionic polymerization using alkali metal hydroxide catalysts, such as sodium hydroxide or potassium hydroxide, or using alkali metal alkoxide catalysts, such as sodium methoxide, sodium ethoxide, potassium ethoxide or potassium isopropoxide, and with addition of at least one starter molecule which comprises from 2 to 8 reactive hydrogen atoms, preferably from 2 to 6 reactive hydrogen atoms, or by cationic polymerization using Lewis acid catalysts, such as antimony pentachloride, boron fluoride etherate, or bleaching earth, the starting materials being one or more alkylene oxides having 2 to 4 carbon atoms in the alkylene radical.

Examples of suitable alkylene oxides are tetrahydrofuran, butylene 1,2- or 2,3-oxide, styrene oxide, and preferably ethylene oxide and/or propylene 1,2-oxide. The alkylene oxides may be used individually, alternating one after the other, or as a mixture. Examples of starter molecules which may be used are: water, organic dicarboxylic acids, such as succinic acid, adipic acid, phthalic acid, or terephthalic acid, aliphatic or aromatic, unsubstituted or N-mono-, or N,N- or N,N′-dialkyl-substituted diamines having from 1 to 4 carbon atoms in the alkyl radical, such as optionally mono- or dialkyl-substituted ethylenediamine, diethylenetriamine, triethylenetetramine, 1,3-propylene-diamine, 1,3- or 1,4-butylenediamine, or 1,2-, 1,3-, 1,4-, 1,5- or 1,6-hexamethylene-diamine.

Other starter molecules which may be used are: alkanolamines, e.g. ethanolamine, N-methyl- or N-ethylethanolamine, dialkanolamines, e.g. diethanolamine, and N-methyl- and N-ethyldiethanolamine, and trialkanolamines, e.g. triethanolamine, and ammonia. It is preferable to use polyhydric alcohols, in particular di- or trihydric alcohols or alcohols with functionality higher than three, for example ethanediol, 1,2-propanediol, 1,3-propanediol, diethylene glycol, dipropylene glycol, 1,4-butanediol, 1,6-hexanediol, glycerol, trimethylolpropane, pentaerythritol, sucrose, and sorbitol. Other suitable components C are esterified polyalkylene glycols, such as the mono-, di-, tri- or polyesters of the polyalkylene glycols mentioned which can be prepared by reacting the terminal OH groups of the polyalkylene glycols mentioned with organic acids, preferably adipic acid or terephthalic acid, in a manner known per se. Polyethylene glycol adipate or polyethylene glycol terephthalate is preferred as component C.

Particularly suitable nonionic surfactants are substances prepared by alkoxylating compounds having active hydrogen atoms, for example adducts of ethylene oxide onto fatty alcohols, oxo alcohols, or alkylphenols. It is preferable to use ethylene oxide or 1,2-propylene oxide for the alkoxylation reaction.

Other preferred nonionic surfactants are alkoxylated or nonalkoxylated sugar esters or sugar ethers.

Sugar ethers are alkyl glycosides obtained by reacting fatty alcohols with sugars, and sugar esters are obtained by reacting sugars with fatty acids. The sugars, fatty alcohols, and fatty acids needed to prepare the substances mentioned are known to the person skilled in the art.

Suitable sugars are described by way of example in Beyer/Walter, Lehrbuch der organischen Chemie, S. Hirzel Verlag Stuttgart, 19th edition, 1981, pp. 392 to 425. Particularly suitable sugars are D-sorbitol and the sorbitans obtained by dehydrating D-sorbitol.

Suitable fatty acids are saturated or singly or multiply unsaturated unbranched or branched carboxylic acids having from 6 to 26 carbon atoms, preferably from 8 to 22 carbon atoms, particularly preferably from 10 to 20 carbon atoms, for example as mentioned in CD Römpp Chemie Lexikon—Version 1.0, Stuttgart/N.Y.: Georg Thieme Verlag 1995, keyword “Fettsäuren” [Fatty acids]. Preferred fatty acids are lauric acid, palmitic acid, stearic acid, and oleic acid.

The carbon skeleton of suitable fatty alcohols is identical with that of the compounds described as suitable fatty acids.

Sugar ethers, sugar esters, and the processes for their preparation are known to the person skilled in the art. Preferred sugar ethers are prepared by known processes, by reacting the sugars mentioned with the fatty alcohols mentioned. Preferred sugar esters are prepared by known processes, by reacting the sugars mentioned with the fatty acids mentioned. Preferred sugar esters are the mono-, di-, and triesters of the sorbitans with fatty acids, in particular sorbitan monolaurate, sorbitan dilaurate, sorbitan trilaurate, sorbitan monooleate, sorbitan dioleate, sorbitan trioleate, sorbitan monopalmitate, sorbitan dipalmitate, sorbitan tripalmitate, sorbitan monostearate, sorbitan distearate, sorbitan tristearate, and sorbitan sesquioleate, a mixture of sorbitan mono- and dioleates.

Very particularly suitable components C are alkoxylated sugar ethers and sugar esters obtained by alkoxylating the sugar ethers and sugar esters mentioned. Preferred alkoxylating agents are ethylene oxide and propylene 1,2-oxide. The degree of alkoxylation is generally from 1 to 20, preferably 2 to 1 0, particularly preferably from 2 to 6. Particularly preferred alkoxylated sugar esters are polysorbates obtained by ethoxylating the sorbitan esters described above, for example as described in CD Römpp Chemie Lexikon—Version 1.0, Stuttgart/N.Y.: Georg Thieme Verlag 1995, keyword “Polysorbate” [Polysorbates]. Particularly preferred polysorbates are polyethoxysorbitan laurate, stearate, palmitate, tristearate, oleate, trioleate, in particular polyethoxysorbitan stearate, which is obtainable, for example, as Tween®60 from ICI America Inc. (described by way of example in CD Römpp Chemie Lexikon—Version 1.0, Stuttgart/N.Y.: Georg Thieme Verlag 1995, keyword “Tween®”)

### Component D

The foils or sheets comprise, as component D, fibrous or particulate fillers or mixtures of these. These are preferably products available commercially, for example carbon fibers and glass fibers. Glass fibers that may be used may be composed of E, A, or C glass, and have preferably been treated with a size and with a coupling agent. Their diameter is generally from 6 to 20 μm. It is possible to use either continuous-filament fibers (rovings) or else chopped glass fibers (staple) whose length is from 1 to 10 mm, preferably from 3 to 6 mm.

It is also possible to add fillers or reinforcing materials, such as glass beads, mineral fibers, whiskers, aluminum oxide fibers, mica, powdered quartz, and wollastonite.

The plastics mixture on which the inventive foils or sheets are based may moreover comprise other additives which are typical of, and familiar in, plastics mixtures.

By way of example of these additives, mention may be made of: dyes, pigments, colorants, antistatic agents, antioxidants, stabilizers for improving heat resistance, for increasing resistance to light, for raising resistance to hydrolysis and to chemicals, agents to counter decomposition by heat, and in particular the lubricants that are advantageous for production of moldings. These other additives may be metered in at any stage of the production process, but preferably at an early juncture, in order that the stabilizing effects (or other specific effects) of the additive may be utilized at an early stage. Heat stabilizers or oxidation retarders are usually metal halides (chlorides, bromides, iodides) derived from metals of group I of the Periodic Table of the Elements (e.g. Li, Na, K, Cu).

Suitable stabilizers are the conventional hindered phenols, but also vitamin E or analogous-structure compounds. HALS stabilizers (Hindered Amine Light Stabilizers), benzophenones, resorcinols, salicylates, benzotriazoles, such as TinuvinRP (the UV absorber 2-(2H-benzotriazol-2-yl)-4-methylphenol from CIBA), and other compounds are also suitable. The amounts of these usually used are up to 2% by weight (based on the entire plastics mixture).

Suitable lubricants and mold-release agents are stearic acids, stearyl alcohol, stearic esters, and generally higher fatty acids, their derivatives, and corresponding fatty acid mixtures having from 12 to 30 carbon atoms. The amounts of these additives are in the range from 0.05 to 1% by weight.

Silicone oils, oligomeric isobutylene, or similar substances may also be used as additives, and the usual amounts are from 0.05 to 5% by weight. It is also possible to use pigments, dyes, color brighteners, such as ultramarine blue, phthalocyanines, titanium dioxide, cadmium sulfides, derivatives of perylenetetracarboxylic acid.

The amounts usually used of processing aids and stabilizers, such as UV stabilizers, lubricants, and antistatic agents, are from 0.01 to 5% by weight.

### Process for Production of Extruded Foils or Sheets

Preparation of the Thermoplastic Molding Compositions for Production of the Inventive foils or sheets composed of components A, B, and, if present, C and D takes place by processes known to the person skilled in the art, for example via mixing of the components in the melt, using apparatuses known to the person skilled in the art, at temperatures which, depending on the nature of the polymer A used, are usually in the range from 150 to 300° C., in particular from 200 to 280° C. Each of the components here may be fed in pure form to the mixing apparatuses. However, it is also possible to begin by premixing individual components, for example A and B, and then to mix these with further components A or B or with other components, such as C and D. In one embodiment, a concentrate is first prepared, for example of components B, C, or D in component A (these being known as additive masterbatches), and is then mixed with the desired amounts of the remaining components. The plastics mixtures may be processed by processes known to the person skilled in the art to give pellets in order then to be processed to give the inventive foils or sheets at a later time, for example by extrusion, calendering, or compression molding. However, they may also be processed, in particular extruded directly following the mixing procedure or in a single operation with the mixing procedure (i.e. simultaneous mixing in the melt and preferably extrusion, preferably by means of a screw extruder), to give the inventive foils or sheets.

In one preferred embodiment of the inventive processes using extrusion, the design of the screw extruder is that of a single-screw extruder with at least one distributively mixing screw element.

In another preferred embodiment of the inventive processes, the design of the screw extruder is that of a twin-screw extruder with at least one distributively mixing screw element.

The processes for extrusion of the inventive foils or sheets may be carried out by methods described in the prior art and known to the person skilled in the art, e.g. slot extrusion in the form of adapter coextrusion or die coextrusion, and using the apparatuses described in the prior art and known to the person skilled in the art.

Depending on the polymer used as component A, the nature and amount of the other components are selected in such a way that the plastics mixtures comprising components A, B, and, if present, C and D have, according to the invention, ultimate tensile strength values within the following ranges:

from 10% to 1000%, preferably from 20% to 700%, preferably from 50% to 500% (for S-TPE and polyethylene as component A), from 10% to 300%, preferably from 12% to 200%, preferably from 15% to 150% (for polypropylene as component A),
from 20% to 300%, preferably from 30% to 250%, particularly preferably from 40% to 200% (for polycarbonates as component A),
from 10% to 300%, preferably from 15 to 250%, particularly preferably from 20% to 200% (for styrene polymers and PVC as component A).

### Composite Layered Sheets or Composite Layered Foils

The inventive foils or sheets are particularly suitable as outer layer (3) of multilayer composite layered sheets or of multilayer composite layered foils, which in addition to the outer layer also have at least one substrate layer (1) composed of thermoplastic. In other embodiments, the composite layered sheets or composite layered foils may comprise additional layers (2), by way of example color layers, adhesion-promoter layers, or intermediate layers, arranged between the outer layer (3) and the substrate layer (1).

The substrate layer (1) can in principle be composed of any thermoplastic. The substrate layer (1) is preferably produced from the following materials described above in the context of the foils or sheets: impact-modified vinylaromatic copolymers, thermoplastic elastomers based on styrene, polyolefins, polycarbonates, and thermoplastic polyurethanes, or their mixtures, particularly preferably from ASA, ABS, SAN, polypropylene, and polycarbonate, or their mixtures.

Layer (2) differs from layers (1) and (3), for example by virtue of a polymer constitution differing from these and/or additive contents distinct from these, for example colorants or special-effect pigments. By way of example, layer (2) may be a coloring layer which preferably can comprise the following materials known to the person skilled in the art: dyes, color pigments, or special-effect pigments, such as mica or aluminum flakes. However, layer (2) may also serve to improve the mechanical stability of the composite layered sheets or composite layered foils, or serve to promote adhesion between the layers (1) and (3).

One embodiment of the invention provides a composite layered sheet or composite layered foil composed of a substrate layer (1) as described above, an outer layer (3), and, situated between these, an intermediate layer (2) which is composed of aliphatic thermoplastic polyurethane, of impact-modified polymethyl methacrylate (PMMA), of polycarbonate, or of styrene (co)polymers, such as SAN, which may have been impact-modified, examples being ASA or ABS, or mixtures of these polymers.

If aliphatic thermoplastic polyurethane is used as material of the intermediate layer (2), it is possible to use the aliphatic thermoplastic polyurethane described for layer (3).

If polycarbonate is used as intermediate layer (2), it is possible to use the polycarbonate described for layer (3).

Impact-modified PMMA (high-impact PMMA or HIPMMA) is a polymethyl methacrylate which has been rendered impact-resistant by virtue of suitable additives. Examples of suitable impact-modified PMMAs are described by M. Stickler, T. Rhein in Ullmann's Encyclopedia of Industrial Chemistry Vol. A21, pages 473-486, VCH Publishers Weinheim, 1992, and H. Domininghaus, Die Kunststoffe und ihre Eigenschaften [Plastics and their properties], VDI-Verlag Düsseldorf, 1992.

The layer thickness of the above composite layered sheets or composite layered foils is generally from 15 to 5000 μm, preferably from 30 to 3000 μm, particularly preferably from 50 to 2000 μm.

In one preferred embodiment of the invention, the composite layered sheets or composite layered foils are composed of a substrate layer (1) and of an outer layer (3) with the following layer thicknesses: substrate layer (1) from 50 μm to 1.5 mm; outer layer (3) from 10 to 500 μm.

In another preferred embodiment of the invention, the composite layered sheets or composite layered foils are composed of a substrate layer (1), of an intermediate layer (2), and of an outer layer (3). Composite layered sheets or composite layered foils composed of a substrate layer (1), of an intermediate layer (2), and of an outer layer (3) preferably have the following layer thicknesses: substrate layer (1) from 50 μm to 1.5 mm; intermediate layer (2) from 50 to 500 μm; outer layer (3) from 10 to 500 μm.

The inventive composite layered sheets or composite layered foils may also have, in addition to the layers mentioned, on that side of the substrate layer (1) facing away from the outer layer (3), other layers, preferably an adhesion-promoter layer, which serve for better adhesion of the composite layered sheets or composite layered foils with the backing layer which remains to be described below. Adhesion-promoter layers of this type are preferably produced from a material compatible with polyolefins, for example SEBS (styrene-ethylene-butadiene-styrene copolymer, e.g. marketed with the trademark Kraton®). If this type of adhesion-promoter layer is present, its thickness is preferably from 10 to 300 μm.

The composite layered sheets or composite layered foils may be produced by processes that are known and described in the prior art (for example in WO 04/00935), e.g. via adapter extrusion or coextrusion or lamination or laminating of the layers to one another. In the coextrusion processes, the components forming the individual layers are rendered flowable in extruders and, by way of specific apparatuses, are brought into contact with one another in such a way as to give the composite layered sheets or composite layered foils with the layer sequence described above. By way of example, the components can be coextruded through a slot die or a coextrusion die. EP-A2 0 225 500 explains this process.

They may also be produced by the adapter coextrusion process, as described in the proceedings of the extrusion technology conference “Coextrusion von Folien”, Oct. 8 and 9, 1996, VDI-Verlag Düsseldorf, in particular in the paper by Dr. Netze. Use is usually made of this cost-effective process whenever coextrusion is used.

The inventive composite layered sheets and composite layered foils may also be produced via mutual lamination or mutual laminating of foils or sheets in a heatable nip. Here, foils or sheets are first produced separately, corresponding to the layers described. Known processes can be used for this purpose. The desired layer sequence is then produced via appropriate mutual superposition of the foils or sheets, and then, by way of example, these are passed through a heatable nip between rolls and are bonded with exposure to pressure and heat to give a composite layered sheet or composite layered foil.

In particular in the case of the adapter coextrusion process, matching of the flow properties of the individual components is advantageous for formation of uniform layers in the composite layered sheets or composite layered foils.

### Moldings

The foils or sheets and the composite layered sheets or composite layered foils comprising the inventive foils or sheets can be used to produce moldings. Any desired moldings are accessible here, preference being given to sheet-like moldings, in particular large-surface-area moldings. These foils or sheets and composite layered sheets or composite layered foils are particularly preferably used for production of moldings in which very good toughness values, good adhesion of the individual layers to one another, and good dimensional stability are important, thus by way of example minimizing breakdown via peel of the surfaces. Particularly preferred moldings have monofoils or composite layered sheets or composite layered foils comprising the inventive foils or sheets and a backing layer composed of plastic applied to the back of the material by an injection-molding, foaming, casting, or compression-molding process.

Processes that are known and described by way of example in WO 04/00935 can be used for production of inventive moldings from the foils or sheets or from the composite layered sheets or composite layered foils (the processes for further processing of composite layered sheets or composite layered foils being described below, but these processes also being capable of use for further processing the inventive foils or sheets). The material can be applied to the back of the composite layered sheets or composite layered foils by an injection-molding, foaming, casting, or compression-molding process, without any further stage of processing. In particular, the use of the composite layered sheets or composite layered foils described permits production even of slightly three-dimensional components without prior thermoforming. The composite layered sheets or composite layered foils may, however, also be subjected to a prior thermoforming process.

By way of example, it is possible to thermoform composite layered sheets or composite layered foils with the three-layered structure composed of substrate layer, intermediate layer, and outer layer, or the two-layer structure composed of substrate layer and outer layer, to produce relatively complex components. Either positive or negative thermoforming processes can be used here. Appropriate processes are known to the person skilled in the art. The composite layered sheets or composite layered foils here are oriented in the thermoforming process. Since the surface quality and metalizability of the composite layered sheets or composite layered foils does not decrease with orientation at high orientation ratios, for example up to 1:5, there are almost no restrictions relating to the possible orientation in the thermoforming processes. After the thermoforming process, the composite layered sheets or foils can be subjected to still further shaping steps, for example profile-cuts.

The inventive moldings can be produced, if appropriate after the thermoforming processes described, by applying material to the back of the composite layered sheets or composite layered foils via injection-molding, foaming, casting, or compression-molding processes. These methods are known to the person skilled in the art and are described by way of example in DE-A1100 55 190 or DE-A1199 39 111.

The inventive moldings are obtained by applying plastics material to the back of the composite layered foils via injection-molding, foaming, casting, or compression-molding processes. The plastics material applied in these injection-molding, compression-molding, or casting processes preferably comprises thermoplastic molding compositions based on ASA polymers or on ABS polymers, on SAN polymers, on poly(meth)acrylates, on polyether sulfones, on polybutylene terephthalate, on polycarbonates, on polypropylene (PP), or on polyethylene (PE), or else blends composed of ASA polymers or of ABS polymers and of polycarbonates or polybutylene terephthalate, and blends composed of polycarbonates and polybutylene terephthalate, and if PP and/or PE is used here it is clearly possible to provide the substrate layer in advance with an adhesion-promoter layer. Particularly suitable materials are amorphous thermoplastics and their blends. A plastics material preferably used for application to the back of the material by an injection-molding process is ABS polymers or SAN polymers. In another preferred embodiment, thermoset molding compositions known to the person skilled in the art are used for application to the back of the material by a foaming or compression-molding process. In one preferred embodiment, these are glass-fiber-reinforced plastics materials, and suitable variants are in particular described in DE-A1100 55 190. For application to the back of the material by a foaming process it is preferable to use polyurethane foams, for example those described in DE-A1199 39 111.

In one preferred process for producing the inventive moldings, the composite layered sheet or composite layered foil is thermoformed and then placed in a back-molding mold, and thermoplastic molding compositions are applied to the back of the material by an injection-molding, casting, or compression-molding process, or thermoset molding compositions are applied to the back of the material by a foaming or compression-molding process.

After thermoforming and prior to placement in the back-molding mold, the composite layered sheet or composite layered foil may undergo a profile-cut. The profile-cut can also be delayed until after removal from the back-molding mold.

### Metalized Polymer Products

The inventive foils or sheets, or composite layered foils or composite layered sheets, and moldings are particularly suitable for production of metalized polymer products without any need for specific pretreatment of the surface of the foils or sheets, or composite layered foils or composite layered sheets, and moldings.

Suitable processes for production of the inventive metalized polymer products are in principle any of the processes described in the literature and known to the person skilled in the art for the deposition of metals by a currentless or electroplating method on plastics surfaces (by way of example see Harold Ebneth et al., Metallisieren von Kunststoffen: Praktische Erfahrungen mit physikalisch, chemisch und galvanisch metallisierten Hochpolymeren [Metalizing of plastics: Practical experience with high polymers metalized by physical, chemical, and electroplating methods], Expert Verlag, Renningen-Malmsheim, 1995, ISBN 3-8169-1037-8; Kurt Heymann et al., Kunststoffinetallisierung: Handbuch für Theorie und Praxis [Metalization of plastics: Manual of theory and practice], No. 22 in the series entitled Gaivanotechnik und Oberflächenbehandlung [Electroplating technology and surface treatment], Saulgau: Leuze, 1991; Mittal, K. L. (ed.), Metallized Plastics Three: Fundamental and Applied Aspects, Third Electrochemical Society Symposium on Metallized Plastics: Proceedings, Phoenix, Ariz., Oct. 13-18, 1991, New York, Plenum Press).

After the respective final shaping process, the inventive foils or sheets, of the composite layered foils or composite layered sheets, or the moldings are usually brought into contact with an acidic, neutral or basic metal salt solution by a currentless or electroplating method, where the normal electrode potential of the metal of this metal salt solution in corresponding acidic, neutral or basic solution is more positive than that of component B. Preferred metals whose normal electrode potential in acidic, neutral or basic solution is more positive than that of component B are gold and silver (if component B is copper), or copper, nickel, and silver, in particular copper, (if component B is iron). A layer M_{S} is thus deposited by a currentless or electroplating method on that layer of the inventive foils or sheets, of the composite layered foils or composite layered sheets, or of the moldings which comprises component B. Preferred layers M_{S} are gold layers and silver layers (if component B is copper), or copper layers, nickel layers, or silver layers, in particular copper layers (if component B is iron).

The thickness of the layer M_{S} that can be deposited by a currentless method is in the usual range known to the person skilled in the art and is not significant for the invention.

The processes described in the literature and known to the person skilled in the art can be used to apply one or more metal layers M_{g}, preferably by an electroplating method, i.e. with application of external potential and passage of current, to the layer M_{S} that can be deposited by a currentless method. It is preferable to deposit copper layers, chromium layers, silver layers, gold layers, and/or nickel layers by an electroplating method, Deposition of layers M_{g} composed of aluminum by an electroplating method is also preferred. Another possibility is application via direct metalization by means of vacuum vapor deposition, bombardment/spraying, or sputtering by the methods known to the person skilled in the art.

The thicknesses of the one or more layers M_{g} deposited are in the conventional range known to the person skilled in the art and are not significant for the invention.

Particularly preferred metalized polymer products for use as electrically conducting components, in particular printed circuit boards, have a copper layer deposited by a currentless method and at least one other layer deposited by an electroplating method.

Particularly preferred metalized polymer products for use in the decorative sector have a copper layer deposited by a currentless method and thereupon a nickel layer deposited by an electroplating method, and a chromium layer, silver layer, or gold layer deposited on that layer.

The inventive foils or sheets, composite layered foils or composite layered sheets, and moldings comprising component B are suitable, without subsequent metalization, as EMI shielding systems (i.e. shielding for avoidance of what is known as electro-magnetic interferences, such as absorbers, attenuators, or reflectors for electromagnetic radiation or as oxygen scavengers.

The inventive metalized polymer products comprising a metal layer M, that can be deposited by a currentless method are suitable, without further deposition of any metal layer M_{g}, as electrically conducting components, in particular printed circuit boards, transponder antennas, switches, sensors, and MIDs, and EMI shielding systems, such as absorbers, attenuators, or reflectors for electromagnetic radiation, or as gas barriers.

The metalized polymer products comprising a metal layer M, that can be deposited by a currentless method and at least one deposited metal layer M_{g} are suitable as electrically conducting components, in particular printed circuit boards, transponder antennas, switches, sensors, and MIDs, and EMI shielding systems, such as absorbers, attenuators, or reflectors for electromagnetic radiation, or gas barriers, or decorative parts, in particular decorative parts in the motor vehicle sector, sanitary sector, toy sector, household sector, and office sector.

Examples of these uses are: computer cases, cases for electronic components, military and non-military screening equipment, shower fittings, washstand fittings, shower heads, shower rails and shower holders, metalized door handles and door knobs, toilet-paper-roll holders, bathtub grips, metalized decorative strips on furniture and on mirrors, frames for shower partitions.

Mention may also be made of: metalized plastics surfaces in the automobile sector, e.g. decorative strips, exterior mirrors, radiator grilles, front-end metalization, aerofoil surfaces, exterior bodywork parts, door sills, tread plate substitute, decorative wheel covers.

In particular, parts which hitherto have been to some extent or entirely produced from metals can be produced from plastic. Examples which may be mentioned here are: tools, such as pliers, screwdrivers, drills, drill chucks, saw blades, ring spanners and open-jaw spanners.

The metalized polymer products are also used—if they comprise magnetizable metals—in sectors for magnetizable functional parts, such as magnetic panels, magnetic games, magnetic areas in, for example, refrigerator doors. They are also used in sectors where good thermal conductivity is advantageous, for example in foils for heated seats, heated floors, insulating materials.

When comparison is made with known metalizable plastics parts, the inventive metalizable plastics parts have improved mechanical properties, in particular improved toughness, flexural strength and formability, and also improved processing properties, for example in forming processes for production involving complex molding of components, and are metalizable without specific pretreatment of the plastics surface, while having comparably good usage properties with respect to, by way of example, metalizability by currentless and electroplating methods, and absorption, attenuation, and reflection of electromagnetic radiation, or oxygen absorption.

Examples are used below to provide further illustration of the invention,

The component A used comprised:
A1. Styroflex® 2G66, a S-TPE from BASF Aktiengesellschaft whose tensile strain at break is 480% and whose tensile strength is 13.9 MPa
A2. Polypropylene, a commercially available homopolypropylene of moderate flowability
A3: Styrolux® 3G55 from BASF Aktiengesellschaft
A4: Ecoflex® F BX 7011, an aliphatic-aromatic copolyester from BASF Aktiengesellschaft whose tensile strain at break is 560% and 710% (parallel and, respectively, perpendicularly to the preferential direction) and whose tensile strength is 29.8 MPa.

The component B used comprised:

B1. Carbonyl iron powder (Type SQ) from BASF Aktiengesellschaft, the diameter of all of whose powder particles is from 1 to 8 μm.

### EXPERIMENTAL SERIES 1

In each case, a plastics mixture was prepared from 1 part by weight of A1 and 17 parts by weight of B1, and, respectively, 1 part by weight of A and 17 parts by weight of B1 in a kneader (IKAVISC MKD H60 laboratory kneader) at temperatures of from 140 to 190° C. In each case a free-flowable powder was obtained, and was then compounded in a DSM miniextruder with sufficient of component A3 to give 89% content by weight of component B1, based on the total weight of the plastics mixtures.

Each of these plastics mixtures was then injection-molded at 220° C. to give test specimens, and tensile strain at break values and tensile strength values were determined in the tensile test to ISO 527-2:1996 on test specimens of 1 BA type (annex A of the stated standard: “small test specimens”).

From each of the plastics mixtures, a pressed foil was produced with thickness 100 μm, at a temperature of 200° C., the pressure in the press being 200 bar. Each of the foils obtained was placed in an injection mold (60×60×2 mm plaques with film gate), and Styrolux® 3G55 was applied at 200° C. to the back of the material by an injection-molding process (Netstal in-mold-coating injection-molding machine with semiautomatic control, screw diameter 32 mm, needle valve nozzle, sprue gate, plaque mold of thickness 4 mm and area 200×100 mm, screw rotation rate 100 rpm, screw advance speed: 50 mm/s, cycle time: 50 S, injection time: 2 s, hold pressure time: 10 s, cooling time: 30 s, plasticizing time: 18 s, cylinder temperature: from 200 to 220° C., mold surface temperature: 34° C. for the plastics mixture comprising A2, and, respectively, 45° C. for the plastics mixture comprising A1).

Each of these in-mold-coating processes gave a composite which could not be delaminated manually (meaning that tension exerted on the foil by 5 test staff did not lead to peeling). A readily visible Cu layer was then formed on the composites via immersion in cupric sulfate solution, within a period of 5 h by a currentless method and, respectively, within a period of 10 min via application of a voltage of from 1 to 2 V.

### EXPERIMENTAL SERIES 2

The quantitative proportions mentioned in table 1 of components A1 and B1 (data in % by weight, in each case based on the entirety of components A1 and B1) were compounded at 200° C. in a DSM miniextruder. Table 1 shows whether elemental copper deposits on immersion of each of the mixtures obtained in an aqueous acidic CuSO₄ solution (pH 4):

TABLE 1

| Experiment | | | |
|---|---|---|---|
| No.* | A1 % by weight | B1 % by weight | Copper deposition |
| 1 comp | 100 | 0 | no |
| 2 | 50 | 50 | no |
| 3 | 30 | 70 | yes |
| 4 | 20 | 80 | yes |
| 5 | 10 | 90 | yes |
| 6** | 5 | 95 | — |

*Experiments indicated by comp are non-inventive and serve for comparison
**Beyond compounding limit

The mixtures obtained in experiment 4 were pressed at 180° C. and 200 bar to give sheets of the thickness stated in table 2. The quality of the resultant sheets is likewise shown in table 2.

TABLE 2

| Experiment No. | Sheet thickness | Sheet quality |
|---|---|---|
| 7 comp | 5 μm | holes |
| 8 | 20 μm | no holes |
| 9 | 100 μm | no holes |
| 10 | 260 μm | no holes |
| 11 | 500 μm | no holes |

*: Experiments indicated by comp are non-inventive and serve for comparison

In order to produce composite layered sheets, the following injection-molding process was used to apply material to the back of the sheets obtained in experiments 8, 9, 10, and 11:

Each of the sheets was placed in an injection mold (60×60×2 mm plaques with film gate), and Styrolux® 3G55 was applied at 200° C. to the back of the material by an injection-molding process (Netstal in-mold-coating injection-molding machine with semiautomatic control, screw diameter 32 mm, needle valve, sprue gate, plaque mold of thickness 4 mm and area 200×100 mm, screw rotation rate 100 rpm, screw advanced speed: 50 mm/s, cycletime: 50 s, injection time: 2 s, hold pressure time: 10 s, cooling time: 30 s, plasticizing time: 18 s, cylinder temperature: 200-220° C., mold surface temperature: 45° C.).

The composite layered sheets produced from the sheets of experiments 8, 9, and 10 could not be delaminated manually, meaning that after material had been applied to the back in an injection-molding process it was impossible to separate the material from the resultant sheets. The composite layered sheet produced from the sheet of experiment 11 could be delaminated manually.

The composite layered sheets produced from the sheets of experiments 8, 9, 10, and 11 were then coppered via immersion of the composite layered sheet in a 5016 strength by weight CuSO₄ solution at 23° C. (pH 1-2, 1 V, 2 A); in each case, copper was visibly deposited within 1 min.

### EXPERIMENTAL SERIES 3

### Experiment 12

A homogeneous mixture was prepared in a twin-screw kneader at temperatures of from 180° C. to 190° C. from 16.4 parts by weight of component A4, 82.2 parts by weight of component B1, and 1.4 parts by weight of Pluronic® PE 6800 (a block copolymer from BASF Aktiengesellschaft composed of 50 mol % of ethylene oxide units and 50 mol % of propylene oxide units) as component C. A tensile strain break of tensile specimens produced from this mixture was 11.8% and their tensile strength was 11.0 MPa, and they could be metalized in a commercially available copper-electroplating bath.

### Experiment 13

A homogeneous mixture was prepared in a twin-screw kneader at temperatures of 180° C. from 19.8 parts by weight of component A1, 79.0 parts by weight of component B1, and 1.2 parts by weight of Emulan® EL (a castor oil ethoxylate) as component C. A tensile strain break of tensile specimens produced from this mixture was 371% and their tensile strength was 5.4 MPa, and they could be metalized in a commercially available copper-electroplating bath.

1. A foil or sheet produced from a plastics mixture comprising, based on the total weight of components A, B, C, and D, which gives a total of 100% by weight,
a from 5 to 50% by weight of a thermoplastic polymer as component A,
b from 50 to 95% by weight of a metal powder with an average particle diameter of from 0.01 to 100 μm (determined by the method defined in the description), where the normal electrode potential of the metal in acidic solution is more negative than that of silver, as component B,
c from 0 to 10% by weight of a dispersing agent as component C, and
d from 0 to 40% by weight of fibrous or particulate fillers or their mixtures as component D,
wherein the tensile strain at break of component A (determined by the method defined in the description) is greater by a factor of from 1.1 to 100 than the tensile strain at break of the plastics mixture comprising components A, B, and, if present, C and D (determined by the method defined in the description), and wherein the tensile strength of component A (determined by the method defined in the description) is greater by a factor of from 0.5 to 4 than the tensile strength of the plastics mixture comprising components A, B, and, if present, C and D (determined by the method defined in the description).

2. The foil or sheet according to claim 1, wherein the tensile strain at break of component A (determined by the method defined in the description) is greater by a factor of from 1.2 to 50 than the tensile strain at break of the plastics mixture comprising components A, B, and, if present, C and D (determined by the method defined in the description), and wherein the tensile strength of component A (determined by the method defined in the description) is greater by a factor of from 1 to 3 than the tensile strength of the plastics mixture comprising components A, B, and, if present, C and D (determined by the method defined in the description).

3. The foil or sheet according to claim 1, wherein the component A used comprises one or more polymers selected from the group of impact-modified vinylaromatic copolymers, thermoplastic elastomers based on styrene, polyolefins, polycarbonates, and thermoplastic polyurethanes.

4. The foil or sheet according to claim 1, wherein the component B used comprises carbonyl iron powder.

5. The foil or sheet according to claim 1, wherein the plastics mixture comprises
a from 5 to 49.9% by weight of component A,
b from 50 to 94.9% by weight of component B,
c from 0.1 to 10% by weight of component C, and
d from 0 to 40% by weight of component D.

6. A thermoplastic molding composition for production of foils or sheets according to claim 1, comprising, based on the total weight of components A, B, C, and D, which gives a total of 100% by weight,
a from 5 to 50% by weight of a thermoplastic polymer as component A,
b from 50 to 95% by weight of a metal powder with an average particle diameter of from 0.01 to 100 μm (determined by the method defined in the description), where the normal electrode potential of the metal in acidic solution is more negative than that of silver, as component B,
c from 0 to 10% by weight of a dispersing agent as component C, and
d from 0 to 40% by weight of fibrous or particulate fillers or their mixtures as component D,
where the tensile strain at break of component A (determined by the method defined in the description) is greater by a factor of from 1.1 to 100 than the tensile strain at break of the thermoplastic molding composition comprising components A, B, and, if present, C and D (determined by the method defined in the description), and where the tensile strength of component A (determined by the method defined in the description) is greater by a factor of from 0.5 to 4 than the tensile strength of the plastics mixture comprising components A, B, and, if present, C and D (determined by the method defined in the description).

7. A pelletized material, comprising the thermoplastic molding composition for production of foils or sheets according to claim 6.

8. A composite layered foil or composite layered sheet, comprising a foil or sheet according to claim 1 as outer layer and at least one substrate layer produced from one or more thermoplastic polymers.

9. A molding comprising a foil or sheet according to claim 1 or a composite layered foil or composite layered sheet, comprising a foil or sheet according to claim 1 as outer layer and at least one substrate layer produced from one or more thermoplastic polymers and a backing layer composed of plastic and applied to the back of the material by an injection-molding, foaming, casting, or compression-molding process.

10. A metalized polymer product comprising a foil or sheet according to claim 1 or a composite layered foil or composite layered sheet, comprising a foil or sheet according to claim 1 as outer layer and at least one substrate layer produced from one or more thermoplastic polymers or a molding comprising a foil or sheet according to claim 1 or a composite layered foil or composite layered sheet, comprising a foil or sheet according to claim 1 as outer layer and at least one substrate layer produced from one or more thermoplastic polymers and a backing layer composed of plastic and applied to the back of the material by an injection-molding, foaming, casting, or compression-molding process, and at least one layer M_{S} that can be deposited by a currentless method onto the layer comprising component B and is composed of a metal, where the normal electrode potential of this metal in acidic solution is more positive than that of component B, and M_{S} is deposited by either a currentless or electroplating method.

11. The metalized polymer product according to claim 10, wherein the layer M_{S} is composed of silver and/or copper and/or nickel, and component B is iron.

12. The metalized polymer product according to claim 10, comprising one or more metal layers M_{g} deposited on the metal layer M_{S} that can be deposited by a currentless method, where M_{S} is deposited by either a currentless or electroplating method.

13. The metalized polymer product according to claim 12, wherein the one or more metal layers M_{g} are composed of copper and/or chromium and/or nickel and/or silver and/or gold, and have been deposited by an electroplating method.

14. A process for production of a foil or sheet according to any of claim 1 via mixing in the melt and extrusion of components A, B, and, if present, C and D.

15. A process for production of a composite layered foil or composite layered sheet according to claim 8, which comprises bonding all of the layers of the composite layered sheet or composite layered foil to one another in the molten state in a coextrusion process.

16. A process for production of a composite layered foil or composite layered sheet according to claim 8, which comprises bonding one or more layers of the composite layered foil or composite layered sheet to one another in a laminating or lamination process in a heated roll nip.

17. A process for production of a molding according to claim 9, which comprises, if appropriate after a thermoforming process, placing the foil or sheet or the composite layered foil or composite layered sheet into a back-molding mold and applying thermoplastic molding compositions to the back of the material by an injection-molding, casting, or compression-molding process, or applying thermoset molding compositions to the back of the material by a foaming or compression-molding process.

18. A process for production of a metalized polymer product according to claim 10, which comprises, after the respective final shaping process, bringing the metalized polymer product according to claim 10 into contact with an acidic, neutral or basic metal salt solution, where the normal electrode potential of this metal in corresponding acidic, neutral or basic solution is more positive than that of component B.

19. A process for production of a metalized polymer product according to claim 10 comprising one or more metal layers M_{g} deposited on the metal layer M_{S} that can be deposited by a currentless method, where M_{S} is deposited by either a currentless or electroplating method, which comprises, after the respective final shaping process, bringing the the metalized polymer product according to claim 10 into contact with an acidic, neutral or basic metal salt solution, where the normal electrode potential of this metal in corresponding acidic, neutral or basic solution is more positive than that of component B and subjecting them or it to a subsequent metalizing process which takes place either via deposition by an electroplating method of metals less noble than silver or via direct metalization by means of vacuum vapor deposition, bombardment/spraying, or sputtering.

20. The method of conducting electricity, absorbing attenuating or reflecting electromagnetic radiation, or scavenging oxygen by metalizing foils or sheets according to claim 1 or of composite layered foils or composite layered sheet, comprising a foil or sheet according to claim 1 as outer layer and at least one substrate layer produced from one or more thermoplastic polymers, or of moldings comprising a foil or sheet according to claim 1 or a composite layered foil or composite layered sheet, comprising a foil or sheet according to claim 1 as outer layer and at least one substrate layer produced from one or more thermoplastic polymers and a backing layer composed of plastic and applied to the back of the material by an injection-molding, foaming, casting or compression-molding process as EMI shielding systems, such as absorbers, attenuators, or reflectors for electromagnetic radiation, or as oxygen scavengers.

21. The method of conducting electricity, absorbing, attenuating or reflecting electromagnetic radiation, or providing a gas barrier by metalizing polymer products according to claim 10 as electrically conducting components, or EMI shielding systems, such as absorbers, attenuators, or reflectors for electromagnetic radiation, or as gas barriers.

22. The method of conducting electricity, absorbing, attenuating or reflecting electromagnetic radiation, or providing a gas barrier by metalizing polymer products according to claim 12 as electrically conducting components, or EMI shielding systems, such as absorbers, attenuators, or reflectors for electromagnetic radiation, or as gas barriers or decorative parts, in particular decorative parts in the motor vehicle sector, sanitary sector, toy sector, household sector, and office sector.

23. An EMI shielding system, such as absorber, attenuator, or reflector for electromagnetic radiation or an oxygen scavenger, comprising extruded foils or sheets according to claim 1 or composite layered foils or composite layered sheets sheet, comprising a foil or sheet according to claim 1 as outer layer and at least one substrate layer produced from one or more thermoplastic polymers, or moldings comprising a foil or sheet according to claim 1 or a composite layered foil or composite layered sheet, comprising a foil or sheet according to claim 1 as outer layer and at least one substrate layer produced from one or more thermoplastic polymers and a baking layer composed of plastic and applied to the back of the material by an injection-molding, foaming, casting, or compression-molding process.

24. An electrically conducting component, or an EMI shielding system, such as absorber, attenuator, or reflector for electromagnetic radiation, or a gas barrier, comprising metalized polymer products according to claim 10.

25. An EMI shielding system, such as absorber, attenuator, or reflector for electromagnetic radiation, a gas barrier, or a decorative part, in particular a decorative part in the motor vehicle sector, sanitary sector, toy sector, household sector, or office sector, comprising metalized polymer products according to claim 12.
